(19) United States
(12) Patent Application Publication
(10) Pub. No.: US 2020/0018709 A1
(43) Pub. Date: Jan. 16, 2020

(54) WAFER DISTORTION MEASUREMENT AND OVERLAY CORRECTION

(71) Applicant: GLOBALFOUNDRIES Inc., Grand Cayman (KY)

(72) Inventors: Erik R. Hosler, Cohoes, NY (US); Moshe Preil, Sunnyvale, CA (US)

(21) Appl. No.: 16/036,066

(22) Filed: Jul. 16, 2018

(51) Int. Cl. G01N 21/956; G03F 7/20; G01N 21/95; H01L 21/67; H01L 23/544; H01L 21/687

(52) U.S. Cl. CPC G01N 21/956; G03F 7/2026; G01N 21/9501; H01L 21/67288; H01L 2223/54426; H01L 21/67259; H01L 23/544; H01L 21/68714; H01L 21/67282

(57) ABSTRACT

A method includes measuring a topography of a semiconductor wafer. A distortion function is generated based on the measured topography. Measured alignment data associated with the semiconductor wafer is adjusted using the distortion function. At least one correction factor for an exposure tool is generated based on the adjusted alignment data. The exposure tool is configured based on the at least one correction factor.

### BACKGROUND

### 1. Field of the Disclosure

Generally, the present disclosure relates to the field of semiconductor processing, and, in particular, to techniques for measuring wafer distortion and correcting overlay based on the distortion.

### 2. Description of the Related Art

Integrated circuits formed on semiconductor wafers typically include a large number of circuit elements, which form an electric circuit. In addition to active devices such as, for example, field effect transistors and/or bipolar transistors, integrated circuits may include passive devices, such as resistors, inductors and/or capacitors.

The formation of IC structures on a wafer is usually facilitated by lithographic processes used to transfer a pattern of a reticle (mask, both terms are used interchangeably herein) to a wafer. Patterns may be formed from a photoresist layer disposed on the wafer by passing light energy through a mask having an arrangement to image the desired pattern onto the photoresist layer. As a result, the pattern is transferred to the photoresist layer. In areas where the photoresist is sufficiently exposed, and after a development cycle, the photoresist material becomes soluble such that it may be removed in order to selectively expose an underlying layer (e.g., a semiconductor layer, a metal or metal-containing layer, a dielectric layer, a hard mask layer, etc.). Portions of the photoresist layer not exposed to a threshold amount of light energy will not be removed and serve to protect the underlying layer during further processing of the wafer (e.g., etching exposed portions of the underlying layer, implanting ions into the wafer, etc.). Thereafter, the remaining portions of the photoresist layer may be removed.

FIG. 1 depicts an illustrative embodiment of a wafer 100 that may be subjected to an exposure process in an exposure tool, (e.g., a stepper/scanner). As shown in FIG. 1, a plurality of die 105 are formed above the wafer 100. The die 105 define the area of the wafer 100 where production integrated circuit devices, e.g., microprocessors, ASICs, memory devices, will be formed. The size, shape and number of die 105 per wafer 100 depend upon the type of device under construction and the size of the wafer 100. The wafer 100 may also have an alignment notch 110 that is used to provide relatively rough alignment of the wafer 100 prior to performing certain processes, e.g., an exposure process in a stepper/scanner tool.

The exposure process performed on the wafer 100 is typically performed on a flash-by-flash basis as the wafer 100 is moved, or stepped, relative to a light source. During each step, the light source (not shown) in the exposure tool projects light onto a given area of the wafer 100, i.e., each flash is projected onto an exposure field 110. The size of the exposure field 110, as well as the number of die 105 within each exposure field 110, may vary greatly.

One of the key parameters in the photolithography process involves accurate overlay positioning, i.e., the process of aligning pattern features in a current layer to previously-patterned features in a previously-formed layer. Overlay is traditionally measured with relatively large test structures which are located in the scribe lines located between production die formed on a semiconductor wafer. A controller provides overlay correction parameters to the exposure tool to increase alignment accuracy.

As the number of process steps and pattern density increases, the shape of the wafer 100 begins to deviate from a flat, round surface. Residual stress from a formed process layer causes curvature of the wafer 100 in free space. Wafer distortion is a significant problem for the most advanced technology nodes in terms of overlay (OVL) correction, a traditionally 2D correction. Wafers 100 are commonly held in chucks while being processed. When a wafer is held in a chuck, the profile of the wafer is changed, however, the new profile is affected by the free space shape as well as the characteristics of the chuck thereby creating a 3D profile.

### SUMMARY

The present invention is directed to a method and system that may solve, or at least reduce, some or all of the aforementioned problems.

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative method disclosed herein includes, among other things, measuring a topography of a semiconductor wafer. A distortion function is generated based on the measured topography. Measured alignment data associated with the semiconductor wafer is adjusted using the distortion function. At least one correction factor for an exposure tool is generated based on the adjusted alignment data. The exposure tool is configured based on the at least one correction factor.

Another illustrative method disclosed herein includes, among other things, securing a semiconductor wafer in a chuck of an exposure tool, measuring a topography of the semiconductor wafer using an optical level sensor while the semiconductor wafer is secured in the chuck, and generating a distortion function based on the measured topography. An expected alignment mark location associated with the semiconductor wafer is adjusted using the distortion function to generate an adjusted alignment mark location. Alignment data associated with the semiconductor wafer is measured based on the adjusted alignment mark location. The alignment data is adjusted using the distortion function. A first set of correction factors is generated for the exposure tool based on the adjusted alignment data. The exposure tool is configured based on the first set of correction factors. The semiconductor wafer is exposed in the exposure tool configured with the first set of correction factors.

An illustrative system disclosed herein includes, among other things, an exposure tool for exposing a semiconductor wafer, a sensor to measure a topography of the semiconductor wafer, and an overlay controller. The overlay controller is to generate a distortion function based on the measured topography, adjust measured alignment data associated with the semiconductor wafer using the distortion function, generate at least one correction factor for the exposure tool based on the adjusted alignment data, and configure the exposure tool based on the at least one correction factor.

### BRIEF DESCRIPTION OF THE DRAWINGS

The disclosure may be understood by reference to the following description taken in conjunction with the accompanying drawings, in which like reference numerals identify like elements, and in which:

FIG. 1 is a simplified diagram of a prior art wafer illustrating exposure fields;

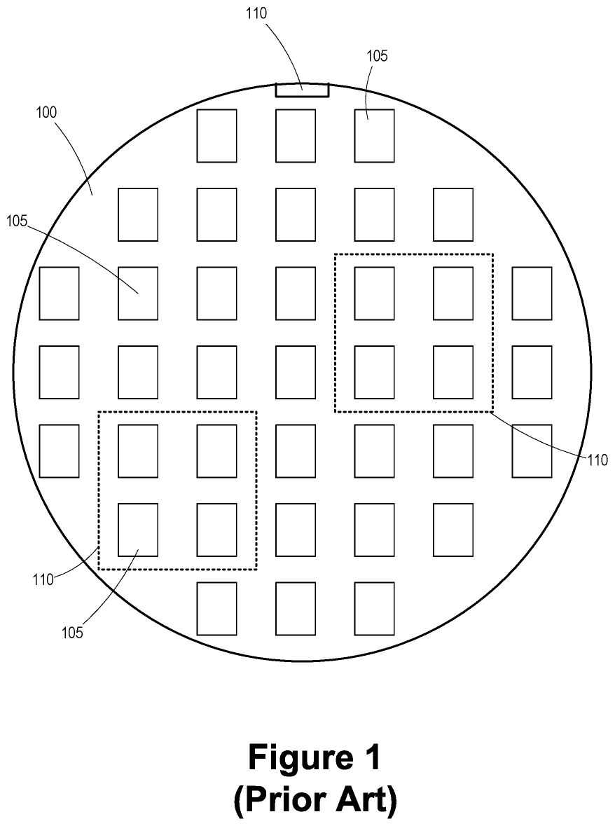

FIG. 2 is a block diagram of a system for performing exposure operations on wafers by measuring wafer distortion and correcting overlay based on the wafer distortion, in accordance with some embodiments; and

FIG. 3 is a flow diagram of one illustrative method for measuring wafer distortion and correcting overlay based on the wafer distortion, in accordance with some embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

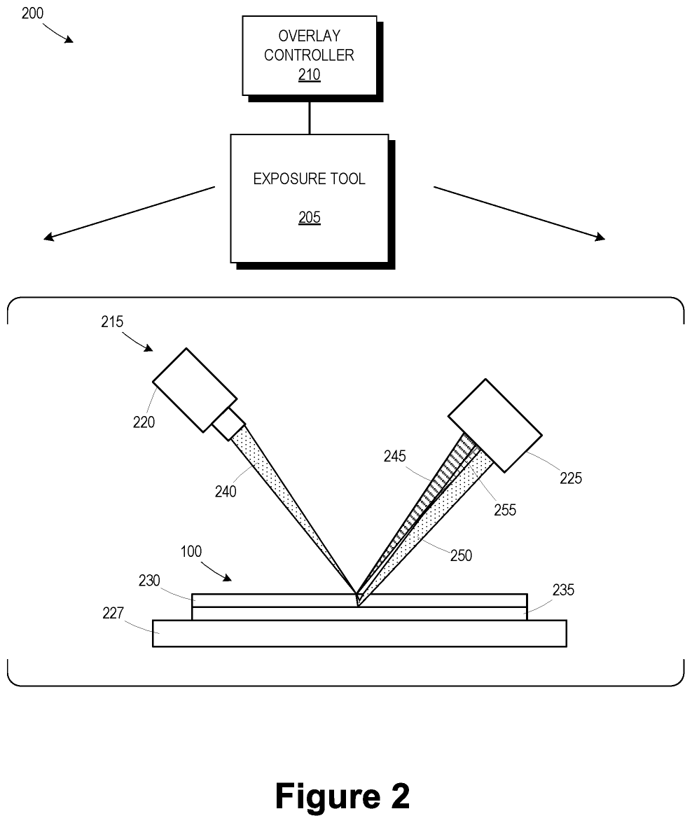

FIG. 2 is a block diagram of a system 200 for performing exposure operations on wafers 100 by measuring wafer distortion and correcting overlay based on the distortion, in accordance with some embodiments. The system includes an exposure tool 205, or stepper/scanner, and an overlay controller 210. The overlay controller 210 provides a plurality of control signals to the exposure tool 205. In some embodiments, the control signals include inter-field control parameters (translation, rotation, magnification) that are applied at the wafer level, and intra-field control parameters (translation, wafer rotation, orthogonality) that are applied for each exposure field. The overlay controller 210 can generally be part of an advanced process control (APC) system. The APC system initiates a control script, which can be a software program, that automatically retrieves the data needed to execute a manufacturing process, such as the exposure process implemented by the exposure tool 205.

The exposure tool 205 includes an optical level sensor 215 including a light source 220 and a detector 225 that measures light from the light source 220 reflected off the wafer 100 as it is held in a chuck 227. For ease of illustration, and to avoid obscuring the present subject matter, the exposure portion of the exposure tool 205 (e.g., photo light source, lenses, reticle, etc.) is not illustrated. The wafer 100 is depicted as having a lithography stack 230 (e.g., bottom anti-reflective coating (BARC) layer, photoresist layer, etc.) for a current photolithography operation formed above a previously-formed process layer stack 235 (e.g., all the previously formed layers and structures on the wafer 100). The optical level sensor 215 is typically employed to determine the distance from the optical level sensor 215 to the uppermost surface of the lithography stack 230 for focus control. Based on the thickness of the lithography stack 230 and the distance to the uppermost surface, the focus settings may be controlled to focus the image in the middle of the lithography stack 230.

In some embodiments, the light source 220 employs a white light beam 240 (e.g., full spectrum). In general, the reflected beam 245 is reflected off the uppermost surface of the lithography stack 230. Other wavelengths, represented as beam 250, pass through the lithography stack 230 to different depths before being reflected back to the detector 225. Interference patterns 255 exist where the beams 245, 250 overlap. The detector 225 collects interference data for different light wavelengths to determine the distance to the upper surface of the lithography stack 230. The intensity data may be converted to distances. Generally, the wavelength having the strongest intensity represents the wavelength reflected off the surface of the lithography stack 230, while the wavelength having the weakest intensity passes through the lithography stack 230 and is reflected off the process layer stack 235.

In typical operation, the level sensor only employs the strongest intensity wavelength to determine the distance to the upper surface of the lithography stack 230 for focus control, and the other interference signals are ignored. As described herein, the overlay controller 210 employs the weakest intensity wavelength signal to determine the distance from the optical level sensor 215 to the process layer stack 235, thereby measuring the topography of the process layer stack 235 (i.e., the curvature of the wafer 100 as it is held in the chuck 227). In general, after convolution with absorption data and the thickness of the lithography stack 230, the weakest wavelength signal provides information on the distance from the optical level sensor 215 to the deepest accessible topography.

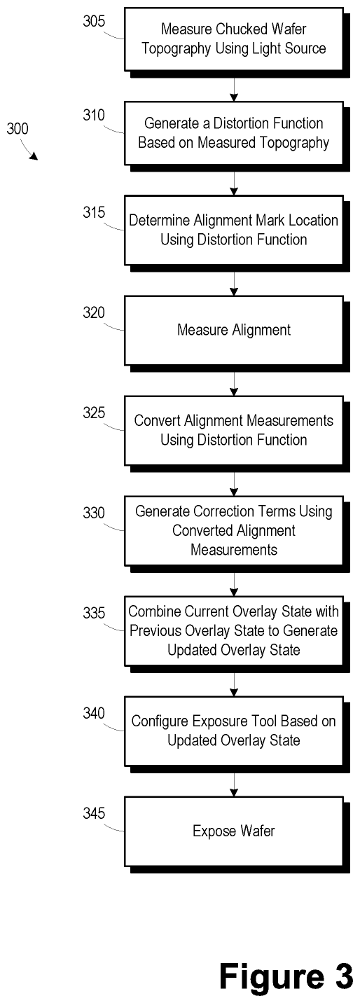

FIG. 3 is a flow diagram of one illustrative method for measuring wafer distortion and correcting overlay based on the distortion, in accordance with some embodiments. The elements of the method 300 may be performed by the overlay controller 210 using topography data measured by the optical level sensor 215 of the exposure tool 205. In method block 305, the topography of the chucked wafer is measured using the optical level sensor 215, as described above. The exposure tool 205 may communicate the raw data (e.g., wavelength interference intensity data) from the optical level sensor 215 to the overlay controller 210, and the overlay controller 210 may determine the wafer topography. In method block 310, a distortion function is generated based on the measured wafer topography. In some embodiments, the distortion function may be a Zernike fitting function, given by the equation:

$$df = {\sum }_{n ∈ N} ( {\sum }_{m ∈ {I}_{n}} {z}_{n}^{m} ( f ) {Z}_{n}^{m} ) .$$

In general, the Zernike function represents the aberration between the actual chucked wafer and an ideal flat wafer. The distortion function may be used to map ideal X,Y coordinates to the distorted coordinate space and vice versa.

In method block 315, the expected alignment mark locations in ideal space X,Y coordinates (AML_{X,Y}) specified in an exposure recipe employed by the overlay controller 210 are adjusted using the distortion function to provide an adjusted location in distorted coordinate space (AML_{DS}), thereby increasing accuracy of the alignment mark search:

AML_{DS}=df(AML_{XY}).

In method block 320, the alignment of the wafer 100 is measured using the alignment marks formed on the wafer. The alignment measurements are in distorted coordinate space since they are affected by the wafer distortion.

In method block 325, the set of alignment measurements are converted from the distorted coordinate space to ideal coordinate space using an inverse of the distortion function:

ALMeas_{XY}=df′(ALMeas_{DS}).

In method block 330, the corrected alignment measurements are used to calculate correction terms for the current wafer. Example correction terms include translation (Tₓ, T_{y}), rotation (Rₓ, R_{y}), and magnification (Mᵣ, M_{y}). Each correction term may be generated using a polynomial model. The parameters of the polynomial models represent a current overlay state for the current wafer. Techniques for generating the correction terms are known to those of ordinary skill in the art, so they are not described in greater detail herein to avoid obscuring the present subject matter.

In method block 335, the current overlay state is combined with the previous overlay state in the overlay controller 210 to generate an updated overlay state. Various techniques, such as an exponentially weighted moving average, may be used to combine the current and previous overlay states. The use of the distortion function allows the current and previous overlay states to be reflected in ideal coordinate space, thereby mitigating the effects of the wafer distortion.

In method block 340, the exposure tool 205 is configured using the updated overlay state. Example equations for configuring the exposure tool 205 to align the reticle and the wafer 100 are given by:

dx(x_{c},y_{c},x_{f},y_{f})=Tₓ(x_{c},y_{c})+Mₓ(x_{c},y_{c})*x_{f}Rₓ(x_{c},y_{c})*y_{f}+k₇*x_{f}²+k₁₁*y_{f}²+k₁₃*x_{f}³+k₁₉*y_{f}³

dy(x_{c},y_{c},x_{f},y_{f})=T_{y}(x_{c},y_{c})+M_{y}(x_{c},y_{c})*x_{f}R_{y}(x_{c},y_{c})*y_{f}+k₈*x_{f}²+k₁₀*y_{f}²+k₁₂*x_{f}³+k₁₄*y_{f}³+k₁₆*x_{f}²y_{f},

where the first lines of the x and y parameters represent linear terms, and the second lines represent higher order terms. The c subscript refers to a correlation relative to a center of the wafer 100, while the f subscript refers to a correlation relative to a center of the exposure field 110.

In method block 345, the wafer is exposed in the exposure tool 205. Measuring the wafer topography using the optical level sensor 215 allows the generation of the distortion function. The distortion function allows expected locations and measurements to be converted between ideal coordinate space and distorted coordinate space to improve the accuracy of the measurements. Incorporating the wafer topography into the overlay control improves the operation of the exposure tool 205 and the quality of the fabricated wafers.

In some embodiments, certain aspects of the techniques described above may be implemented by one or more processors of a processing system executing software. The method 300 described herein may be implemented by executing software on a computing device, such as the overlay controller 210 of FIG. 2; however, such methods are not abstract in that they improve the operation of the exposure tool 205 and the quality of the fabricated wafers. Prior to execution, the software instructions may be transferred from a non-transitory computer readable storage medium to a memory.

The software may include one or more sets of executable instructions stored or other-wise tangibly embodied on a non-transitory computer readable storage medium. The soft-ware can include the instructions and certain data that, when executed by one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory devices, and the like. The executable instructions stored on the non-transitory computer readable storage medium may be in source code, assembly language code, object code, or other instruction format that is interpreted or otherwise executable by one or more processors.

A computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method, comprising:
measuring a topography of a semiconductor wafer;
generating a distortion function based on the measured topography;
adjusting measured alignment data associated with the semiconductor wafer using the distortion function;
generating at least one correction factor for an exposure tool based on the adjusted alignment data; and
configuring the exposure tool based on the at least one correction factor.

2. The method of claim 1, further comprising exposing the semiconductor wafer using the exposure tool configured with the at least one correction factor.

3. The method of claim 1, further comprising:
generating a set of correction factors for the exposure tool, each correction factor comprising a plurality of parameters;
generating current state data for the exposure tool based on the plurality of parameters for each of the correction factors;
combining the current state data with previous state data representing previous values of the plurality of parameters to generate updated state data; and
configuring the exposure tool based on the updated state data.

4. The method of claim 1, further comprising adjusting an expected alignment mark location associated with the semiconductor wafer using the distortion function to generate an adjusted alignment mark location, wherein measuring the alignment data comprises measuring the alignment data using the adjusted alignment mark location.

5. The method of claim 1, wherein the at least one correction factor comprises an x-axis translation correction factor, a magnification correction factor, and a rotation correction factor.

6. The method of claim 1, wherein measuring the topography of the semiconductor wafer comprises:
securing the semiconductor wafer in a chuck of the exposure tool; and
measuring the topography of the semiconductor wafer using an optical level sensor while the semiconductor wafer is secured in the chuck.

7. The method of claim 6, wherein the semiconductor wafer comprises a process layer stack and a lithography stack formed above the process layer stack, and measuring the topography of the semiconductor wafer comprises measuring a distance of the process layer stack from the optical level sensor.

8. The method of claim 1, wherein generating the distortion function comprises generating a Zernike distortion function.

9. A method, comprising:
securing a semiconductor wafer in a chuck of an exposure tool;
measuring a topography of the semiconductor wafer using an optical level sensor while the semiconductor wafer is secured in the chuck;
generating a distortion function based on the measured topography;
adjusting an expected alignment mark location associated with the semiconductor wafer using the distortion function to generate an adjusted alignment mark location;
measuring alignment data associated with the semiconductor wafer based on the adjusted alignment mark location;
adjusting the alignment data using the distortion function;
generating a first set of correction factors for the exposure tool based on the adjusted alignment data;
configuring the exposure tool based on the first set of correction factors; and
exposing the semiconductor wafer in the exposure tool configured with the first set of correction factors.

10. The method of claim 9, further comprising:
generating current state data for the exposure tool based on a plurality of parameters associated with the first set of correction factors;
combining the current state data with previous state data representing previous values of the plurality of parameters to generate updated state data; and
configuring the exposure tool based on the updated state data.

11. A system, comprising:
an exposure tool for exposing a semiconductor wafer;
a sensor to measure a topography of the semiconductor wafer; and
an overlay controller to generate a distortion function based on the measured topography, adjust measured alignment data associated with the semiconductor wafer using the distortion function, generate at least one correction factor for the exposure tool based on the adjusted alignment data, and configure the exposure tool based on the at least one correction factor.

12. The system of claim 11, wherein the exposure tool is to expose the semiconductor wafer after being configured with the at least one correction factor.

13. The system of claim 11, wherein the overlay controller is to generate a set of correction factors for the exposure tool, each correction factor comprising a plurality of parameters, generate current state data for the exposure tool based on the plurality of parameters for each of the correction factors, combine the current state data with previous state data representing previous values of the plurality of parameters to generate updated state data, and configure the exposure tool based on the updated state data.

14. The system of claim 11, wherein the overlay controller is to adjust an expected alignment mark location associated with the semiconductor wafer using the distortion function to generate an adjusted alignment mark location.

15. The system of claim 11, wherein the at least one correction factor comprises a translation correction factor, a magnification correction factor, and a rotation correction factor.

16. The system of claim 11, wherein the exposure tool comprises a chuck to secure the semiconductor wafer, and the sensor comprises an optical level sensor to measure the topography of the semiconductor wafer while the semiconductor wafer is secured in the chuck.

17. The system of claim 16, wherein the semiconductor wafer comprises a process layer stack and a lithography stack formed above the process layer stack, and the optical level sensor is to measure a distance between the process layer stack and the optical level sensor.

18. The system of claim 11, wherein the distortion function comprises a Zernike distortion function.
